(19) United States
(12) Patent Application Publication
(10) Pub. No.: US 2018/0004264 A1
(43) Pub. Date: Jan. 4, 2018

(54) INTEGRATED CIRCUIT POWER DISTRIBUTION WITH THRESHOLD SWITCHES

(71) Applicant: Western Digital Technologies, Inc., Irvine, CA (US)

(72) Inventors: Mac D. Apodaca, San Jose, CA (US); Daniel Bedau, San Jose, CA (US); Daniel Shepard, San Jose, CA (US)

(21) Appl. No.: 15/197,522

(22) Filed: Jun. 29, 2016

(51) Int. Cl. G06F 1/26; G11C 13/00; G06F 13/40

(52) U.S. Cl. CPC G06F 1/266; G06F 13/4027; G11C 13/0038

(57) ABSTRACT

To provide enhanced power distribution in integrated circuits, solid state memory arrays, or other solid state devices, various systems, architectures, apparatuses, and methods, are provided herein. In a first example, an integrated circuit power distribution system is provided. The system includes a first power distribution bus coupled to a current source and a threshold bridge element, and a second power distribution bus coupled to one or more target devices and the threshold bridge element. The threshold bridge element comprises a bridge material with properties that pass current responsive to application of a threshold voltage across the bridge material.

### TECHNICAL FIELD

Aspects of the disclosure are related to the fields of integrated circuits, microfabrication, and power distribution in integrated circuit memory arrays.

### TECHNICAL BACKGROUND

Integrated circuits, such as chip-scale memory devices, microprocessors, and other micro-fabricated circuits can include various signal and power distribution elements to provide links to the various circuits, memory devices, logic elements, and such. These distribution elements can include power busses and power rails formed by metal or metallization-based features as well as data/address links. For example, in memory arrays, such as NAND flash devices, memory cells can be arranged into large arrays which are addressed using wordlines and bit lines. However, these address lines and associated power distribution lines for the memory cells have become increasingly fine pitch along with the memory cells themselves. These fine feature pitches lead to difficulties in distributing power and signals to the various devices embedded in integrated circuits.

In one example, crosspoint arrays are made using very fine geometry wires. Row and column lines made with very fine features will not have the high conductivity desired for very large arrays. High-resistance problems become much worse as the arrays are scaled up in total bit density while downscaling the feature size. Not only does resistance increase with the smaller feature sizes, but interconnect lengths also increase. The combination of these two effects creates a barrier that cannot be overcome with conventional scaling.

### Overview

To provide enhanced power distribution in integrated circuits, solid state memory arrays, or other solid state devices, various systems, architectures, apparatuses, and methods, are provided herein. In a first example, an integrated circuit power distribution system is provided. The system includes a first power distribution bus coupled to a current source and a threshold bridge element, and a second power distribution bus coupled to one or more target devices and the threshold bridge element. The threshold bridge element comprises a bridge material with properties that pass current responsive to application of a threshold voltage across the bridge material.

### BRIEF DESCRIPTION OF THE DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views. While several embodiments are described in connection with these drawings, the disclosure is not limited to the embodiments disclosed herein. On the contrary, the intent is to cover all alternatives, modifications, and equivalents.

FIG. 1 is a system diagram illustrating an integrated circuit.

FIG. 2 is a schematic diagram illustrating operation of power control in an integrated circuit.

FIG. 3 is a system diagram illustrating an integrated circuit.

FIG. 4 is a flow diagram illustrating a method of operating a power control system for an integrated circuit.

### DETAILED DESCRIPTION

Integrated circuits, such as solid state memory arrays, microprocessors, and other micro-fabricated circuits can include various signal and power distribution elements to provide links among the various circuits, memory devices, logic elements, and such. These distribution elements can include power busses and power rails formed by metal or metallization-based features as well as data/address links. As integrated circuits are scaled down in feature size from manufacturing density increases, electrical resistance associated with each of the various busses and links also increase. This can lead to signal degradation, power quality issues, and other problems which can limit feature sizes.

In the examples herein, various enhanced techniques are employed for not only distributing power in integrated circuits, but also providing more efficient data/address signal distribution in integrated circuits. These improvements can lead to technical effects such as greater scalability of integrated circuits, power savings and power distribution efficiency increases, and the ability to increase densities and sizes of integrated circuits. For example, when employed in memory arrays, the examples here can provide for increased memory densities and more efficient power distribution and reduction in heat dissipation.

To provide these enhancements, the various examples can employ bridging elements positioned between large power distribution rails and smaller localized power transfer features. These bridging elements include voltage threshold switches and can comprise various solid state materials that pass current after application of a threshold activation voltage. Even once the activation voltage is removed, these voltage threshold switches can remain activated to pass current. Once the current falls below a threshold level, then the voltage threshold switches can cease passing further current. Some examples of the voltage threshold switches include ovonic threshold switch (OTS) devices, although other suitable materials are possible.

The various examples herein can provide electrical current from a periphery of a cross-point array without being limited by the unfavorable scaling issues described above. The scaling limitations are prevented herein by using a hierarchical set of signal conductors that are interconnected with voltage threshold switch devices. Currents pass through the finest level of interconnects (i.e. at the density of the memory cells) for a short distance, otherwise the currents flow in a wider bus-bar type conductor. A smaller plurality of large geometry signal bus bar conductors crosses a large plurality of finer geometry array lines with a threshold bridge connection, such as an OTS device, from each bus bar to each array line.

To drive a given array line with a low impedance source (i.e. through a power bus bar), the desired drive voltage is applied to the bus bar closest to the portion of the array under which the memory cell to be addressed is located. Once this one corresponding bus bar is powered, the array line corresponding to the memory cell to be addressed is pulled low through a high resistance. This will cause the threshold voltage of the threshold bridge device connected between the powered bus bar and the intended array line to be exceeded thereby causing that threshold bridge device to switch to its low impedance state. When the threshold bridge device switches on, its low ‘on’ impedance will overpower any high impedance of the array line pull down thereby overriding that pull down and causing the array line to be pulled high (at which point the pull down can be switched off). The current path through the memory cell can be connected so as to maintain a holding current of the threshold bridge device. The memory cell device/selector can be of many possible types including phase change memory (PCM)/diode, PCM/OTS, resistive random access memory (ReRAM)/diode, ReRAM/OTS, and the like.

In memory array examples, addressing of a power bus bar can be made using upper bits (as many as desired to address the number of individual power bus bars) of the data address for the orthogonal lines in the memory array. This scheme can be extended to multiple levels, such as three dimensional (3D) layers, of bus bar conductors. The number of conductors increases with the logarithm of the array size so that few bus bar layers are required even for large memory arrays. Thus, a 3D crosspoint architecture is employed using low impedance bus bars connected to memory array lines through selector switches or bridges. As mentioned above, the bridge or selector switch can comprise OTS elements or materials. Moreover, each memory cell might have a corresponding selector switch or bridge. Memory arrays can employ these bridges or selector switches to form combinations of word lines and bit lines.

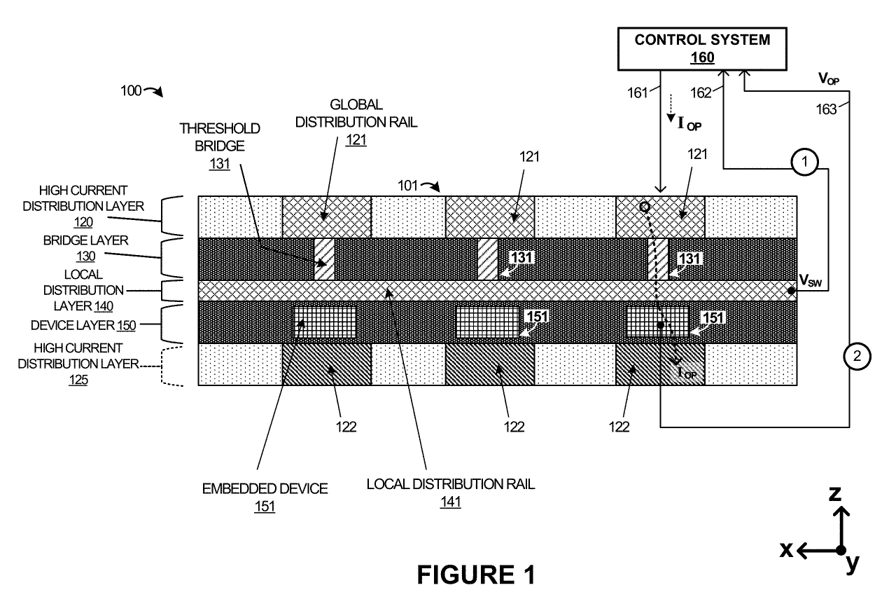

Turning now to the Figures, FIG. 1 is a system diagram illustrating an integrated circuit in an example. FIG. 1 includes system 100 which further includes integrated circuit 101 and control system 160. In some examples, control system 160 comprises logic and power circuitry that is combined with integrated circuit 101 or formed into the same semiconductor substrate as integrated circuit 101. As will be discussed in further detail below, control system 160 can apply associated voltages/currents over links 161-163.

Integrated circuit 101 comprises a plurality of layers of materials which can be formed using semiconductor manufacturing techniques, among other techniques. For example, the features of integrated circuit 101 can be formed using techniques found in semiconductor wafer processing and microfabrication, such as photo-lithography, diffusing, deposition, epitaxial growth, etching, annealing, and ion implanting, among others. It should be understood that the set of layers shown in FIG. 1 is merely exemplary, and a different quantity and configuration can be employed to form the elements discussed herein. For example, layer 125 might be omitted in some examples, or one or more of the layers might be in a different order in the stackup.

A first layer 120 is shown comprising one or more high current distribution elements, namely global distribution rails 121. Global distribution rails 121 span horizontally into the sheet in this example, namely in the ‘y’ axis. Global distribution rails 121 comprise metal portions forming conductive busses and can be embedded into insulating or isolating surrounding material of the layer in some examples. Global distribution rails 121 can be formed from any suitable metal or metalized material, such as copper, aluminum, or metal-doped materials, including combinations thereof. Global distribution rails 121 carry current from a source, such as control system 160, and are of a geometry and material composition to provide a low-resistance path for current over chip-scale levels.

A second layer 130 is shown comprising one or more bridge elements 131. These bridge elements are configured to electrically bridge global distribution rails 121 to local distribution elements in layer 140. Each bridge element 131 can comprise ovonic threshold switch (OTS) elements, among other materials and elements. Geometries of bridge elements 131 can be selected based on desired current performance or threshold voltages for switching the bridge elements into an activated state, among other considerations. Bridge elements 131 can be embedded into insulating or isolating surrounding material of the layer in some examples. In further examples, bridge elements 131 each include interface materials which couple a central threshold switch material to associated metal rails or other nearby structures. These interface materials can comprise conductive materials which isolate the material of the central threshold switch from intrusion by contaminants, such as metals or other materials. Likewise, the interface materials can prevent migration of the central threshold switch materials into associated metal rails and other nearby structures.

A third layer 140 is shown comprising one or more local distribution elements, namely local distribution rails 141. Local distribution rails 141 span horizontally across the sheet in this example, namely in the ‘x’ axis, and more than one local distribution rail will typically be employed and arrayed horizontally in the ‘y’ axis. Thus, local distribution rails 141 and global distribution rails 121 lie generally perpendicular to each other but on separate layers separated by bridge layer 130. Local distribution rails 141 comprise metal portions forming conductive busses and can be embedded into insulating or isolating surrounding material of the layer in some examples. Local distribution rails 141 can be formed from any suitable metal or metalized material, such as copper, aluminum, or metal-doped materials, including combinations thereof. Local distribution rails 141 carry current to one or more target devices, such as embedded devices 151. In typical examples, local distribution rails 141 comprise finer geometries than global distribution rails 121, and thus have correspondingly higher electrical resistances per unit length.

A fourth layer 150 is shown comprising one or more embedded devices 151. These devices can comprise target devices employed during operation of integrated circuit 101. Embedded devices 151 can comprise memory devices, memory cells, transistors, circuits, logic elements, logic gates, processor components, or other semiconductor or ReRAM elements. In some examples, embedded devices 151 are part of a memory array comprising flash memory, resistive memory elements, phase change memory elements, or other memory elements and devices. During operation, global distribution rail 121, threshold bridge elements 131, and local distribution rails 141 provide signal or power distribution to embedded devices 151. Embedded devices 151 can be embedded into insulating or isolating surrounding material of the layer in some examples.

An optional fifth layer 125 can provide further low-resistance interconnect 122, such as provided by layer 120. Interconnect 122 can be coupled to devices 151 or to local distribution elements by further bridge elements, such as found in layer 130. This interconnect 122 can be further coupled to control system 160 or other circuit elements to provide a return current path for elements 151. Further layers can be included in integrated circuit 101 comprised of logic, wafer substrate, interconnect, metallization, or other elements.

In operation, control system 160 can be employed to control the elements of integrated circuit 101, such as to write/read data, control logic circuitry, distribute power, or other operations. In a first example operation, control system 160 initially applies a switching voltage (V_{SW}) across a selected bridging element 131, such as the one indicated in FIG. 1. To apply this switching voltage, control system 160 can apply a voltage across links 161 and 162, which consequently applies the voltage over the associated bridge element 131. One of the global distribution rails 121 is selected to have the voltage applied which, when combined with a selection of local distribution rail 141 (out of a plurality of rails in the horizontal plane), will responsively activate a switching material in an associated bridging element 131.

Once activated, the associated bridging element 131 will begin to pass current between the selected rails 121, 141. However, control system 160 is configured to cease application of the switching voltage once the associated bridging element 131 is activated and passes current. Coincident with application of the switching voltage, control system 160 can also apply an operating signal or voltage (V_{OP}) between links 161 and 163. This operating signal or voltage provides operating current (I_{OP}) for one or more embedded target devices 151. The associated bridging element 131 continues to pass current until the current falls below a threshold current for falls below a threshold current for a threshold amount of time. Thus, using bridging elements 131, a larger geometry/lower resistance distribution rail 121 can be employed to carry operational current to one or more target devices while only having to traverse a short span of a smaller geometry/higher resistance local distribution rail 141.

In memory array examples, control signaling can include controlling bitlines and wordlines which are used to address memory devices to write and read data in the memory devices. In some examples, only entire wordlines are addressable and thus an entire wordline of data is written into associated resistive memory devices simultaneously. Local distribution rails 141 can comprise wordlines or bitlines in memory device examples, and rails 121 can be used to efficiently distribute signals and power to and from wordlines and bitlines. In three-terminal memory devices, such as ReRAM devices or flash memory devices, wordlines and bitlines can be coupled to source/drain or gate terminals to store and retrieve data in the memory devices. Other techniques can be employed to measure and read data from each of the memory devices.

Turning now to the elements of control system 160, control system 160 may be implemented as a single apparatus, system, or device or may be implemented in a distributed manner as multiple apparatuses, systems, or devices. For example, control system 160 can comprise one or more application-specific integrated circuits (ASICs), field-programmable gate arrays (FPGA), or discrete logic and associated circuitry, including combinations thereof. Although not shown in FIG. 1, control system 160 can include communication interfaces, network interfaces, user interfaces, and other elements for communicating with a host system. Control system 160 may optionally include additional devices, features, or functionality not discussed for purposes of brevity.

Control system 160 can also comprise or communicate with one or more microcontrollers or microprocessors with software or firmware included on computer-readable storage media devices. If software or firmware is employed, the computer-readable storage media devices may include volatile and nonvolatile, removable and non-removable media implemented in any method or technology for storage of information, such as computer readable instructions, data structures, program modules, or other data. Examples of storage media include random access memory, read only memory, magnetic disks, resistive memory devices, ReRAM devices, optical disks, flash memory, virtual memory and non-virtual memory, magnetic cassettes, magnetic tape, magnetic disk storage or other magnetic storage devices, or any other suitable storage media.

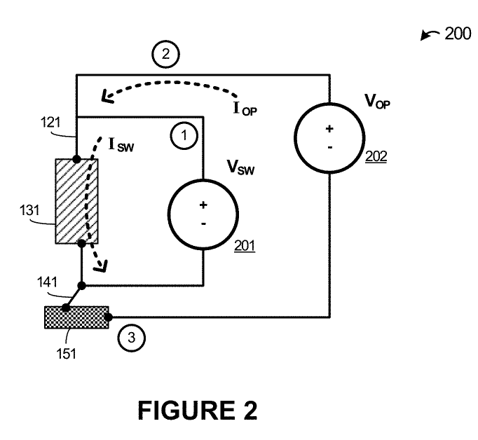

FIG. 2 is a schematic diagram illustrating operation of power control system for an integrated circuit, such as for integrated circuit 101. Further operation of control circuitry 160 can be exemplified by the elements in FIG. 2. Corresponding elements of FIG. 1 are referenced in FIG. 2, although variations are possible. FIG. 2 includes circuit 200 which can be controlled by elements of control circuitry 160, or formed by other elements. Although one device 151 is shown in FIG. 2, it should be understood that multiple devices can be employed, such as when rail 141 is a wordline or a bitline which couples to many memory cells. Furthermore, voltage sources 201-202 are merely exemplary, and might comprise different elements than voltage supplies, such as control circuitry, current sources, power management circuits, read/write circuity, or other elements, including combinations thereof.

Voltage source 201 is configured to apply threshold voltage V_{SW} across at least bridging element 131 to activate bridging element 131 to pass current, as indicated by operation ‘1’ in FIG. 2. V_{SW} can be applied across rail 121 and rail 141 with a corresponding current I_{SW}. Once bridging element 131 is activated, voltage source 202 can be activated to apply operational voltage V_{OP} to device 151 and likewise operational current I_{OP} will flow to device 151. V_{OP} can be applied across rail 121 and device 151, as indicated by operation ‘2’ in FIG. 2. Also, once bridging element 131 is activated, V_{SW} can be removed or otherwise halted, and bridging element 131 will remain activated until I_{OP} falls below a threshold current. Once I_{OP} falls below the threshold current, then bridging element 131 will deactivate and cease to pass current until the threshold voltage is applied again. During the timeframe that bridging element 131 is activated, device 151 can be accessed using I_{OP}, as indicated by operation ‘3’ in FIG. 2. This access can include reading data, writing data, or other operations. Furthermore, I_{OP} can be modulated by a control circuit, such as voltage source 202, to operate or control device 151 for writing or reading data, among other operations.

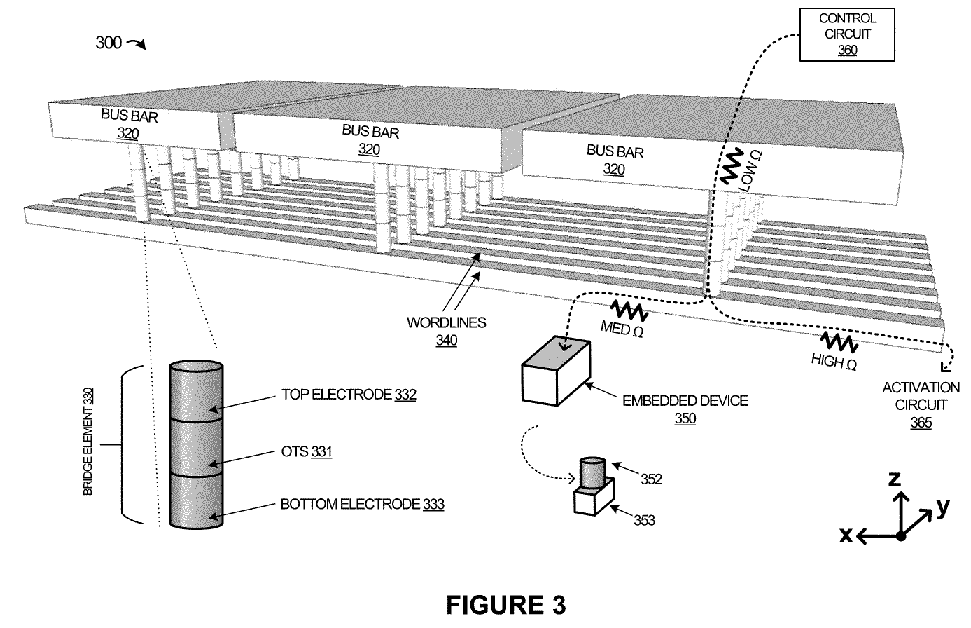

FIG. 3 is a system diagram illustrating an integrated circuit. Specifically, FIG. 3 shows an isometric view of elements of distribution system 300. Distribution system 300 can be employed in an integrated circuit, such as that shown in FIG. 1. FIG. 3 is presented to focus on various elements of a distribution system in an integrated circuit, and it should be understood that further elements can be included in physical implementations. Distribution system 300 can distribute power, current, signals, or data among elements of an integrated circuit. Using the elements of FIG. 3, low-resistance pathways formed by any of bus bars 321 can efficiently carry power, current, signals, or data to and from target devices that are embedded in central regions of an integrated circuit. In many examples, power, current, signals, or data are transported from the periphery or edges of the integrated circuit.

System 300 includes bus bars 320, bridge elements 330, word lines 340, and one or more embedded devices 350. As can be seen in FIG. 3, bus bars 320 run along the y-axis and are generally perpendicular to wordlines 340 which run along the x-axis. In typical examples, bus bars 320, bridge elements 330, word lines 340, and embedded devices 350 are layered onto a substrate and built-up in the z-axis to form an integrated circuit. In some examples, an embedded device can further be coupled to an individual OTS element, such as shown for elements 352 and 353.

Bus bars 320 and wordlines 340 each comprise metal or metalized materials which provide a conduction path for current. Each bus bar 320 and wordline 340 can be separately accessed, such as during addressing or data operations, and can have a voltage separately applied with a corresponding current. Wordlines 340 are coupled to embedded devices, such as embedded device 350. Wordlines 340 can be coupled to control circuitry, such as portions of control circuit 360 or activation circuit coupled at an end of each of wordlines 340. Bus bar 320 is coupled to control circuitry, such as control circuit 360 in FIG. 3.

Bridge elements 330 each further comprise top electrode 332, OTS 331, and bottom electrode 333. Electrodes 332-333 comprise interface materials which couple a OTS material to associated metal rails or other nearby structures. Electrodes 332-333 can comprise conductive materials which chemically isolate the material of the central threshold switch from intrusion by contaminants, such as metals or other materials. Likewise, electrodes 332-333 can prevent migration of the OTS materials into associated metal rails and other nearby structures. Electrodes 332-333 are configured to pass current from an associated bus bar or wordline to/from the OTS material and inhibit migration of atomic/ionic material of the bus bar or wordline into the OTS material, and vice versa.

OTS (ovonic threshold switch) elements discussed herein, such as OTS 331 comprises solid state devices that can be activated to pass current once a threshold voltage is applied across the material. Once the threshold voltage is removed, the current continues to flow until the current is halted or falls below a threshold level. Modulations can be applied to the current without disabling the OTS activation in some examples. OTS elements can comprise a phase change material composed of germanium, antimony tellurium, or other materials, with possible additional dopant materials added comprising arsenic, selenium, sulfur, indium, or other materials.

Embedded devices 350 can comprise memory devices, such as non-volatile memory (NVM) arrays, ReRAM devices or other resistive memory elements, phase change memory elements, NAND/NOR flash elements, dynamic or static random access memory cells. In other examples, embedded devices 350 can comprise logic circuity, such as arithmetic/logic circuits, shift registers, transmission gates, logic gates, or combinations of logic and memory elements. Embedded devices 350 are controlled by control circuit 360 or other circuitry to operate embedded devices 350, such as reading/writing data, engaging a logic function, transferring input/output bits, or other operations.

In further examples, additional optional OTS elements can be included proximate to embedded devices, such as shown in FIG. 3 for elements 352-353. This additional OTS element can provide further electrical isolation or selection options for individually selecting one or more embedded devices. Additional OTS elements can be included ‘above’ or ‘below’ embedded devices and between the embedded device and an associated wordline or conductive element below the embedded device. This configuration can be helpful when additional bus lines or word/bit lines are employed ‘below’ the embedded devices which run perpendicular to wordlines 340.

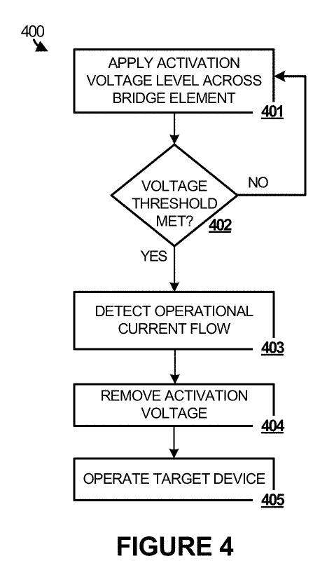

In operation, bus bars 320, bridge elements 330, and wordlines 340 can be used to transfer power to target embedded devices 350. In some examples, bus bars 320, bridge elements 330, and wordlines 340 can transport data bits, control signals, communication signals or other signaling and data. Initially, current or signals cannot reach a selected embedded device due to the corresponding OTS element being deactivated or ‘off’ from passing current or signals. An activation process is engaged in by control circuitry, such as by activation circuit 365, and this process is discussed in more detail in FIG. 4.

FIG. 4 is a flow diagram illustrating a method of operating a control system for an integrated circuit. This control system can comprise control circuit 360 and activation circuit 365 in FIG. 3, or can include additional elements as found in FIGS. 1 and 2. In FIG. 4, the control system applies (401) an activation voltage level across a selected bridge element. In FIG. 3, activation circuit 365 can apply a voltage across a selected OTS element by applying a voltage across a bus bar and wordline that intersect at the selected OTS element. It should be understood that activation circuit 365 can be positioned and operated at both ends of the wordlines, or at only a selected end. This activation voltage, once a voltage threshold is met (402), will activate a selected OTS element, and the selected OTS element will responsively pass current.

As seen in FIG. 3, due to inherent resistances of bus bar and wordline elements, a current might flow through the low resistance bus bar (low Ω), the selected OTS element, and a portion of the wordline used to apply the activation voltage (high Ω). However, the high resistance of the small geometry/pitch of the associated wordline will limit the current that flows responsive to the activation voltage turning on the OTS element. If the selected device is proximate an edge or end of the array, this portion of the wordline could have a lower resistance (low to medium Ω) so current limiting in the activation circuit 365 can be employed, such as by a using a current limiting circuit or resistor in activation circuit 365. A larger current will flow from the bus bar (low Ω) through the OTS element and to one or more of the embedded devices connected to the selected wordline (medium Ω). This current can be used to operate (405) the target embedded devices by providing a low-resistance pathway to the embedded device through the OTS element and associated large geometry/pitch bus bar. Although a current is discussed above, the current can comprise a signal, data, power, or other electrical flow enabled by activation of the selected OTS element.

Activation circuit 365 can detect operational current flow (403) to the one or more embedded devices and responsively remove the activation voltage (404). This detection can comprise determining a timing of activation once a desired voltage is applied across the selected OTS element, and removing the activation voltage once a timing threshold has been met. In other example, this detection can comprise detecting a voltage drop between the selected bus bar and the selected wordline. Specifically, when the activation voltage is applied across the selected bus bar and the selected wordline but the OTS element bridging the selected bus bar and the selected wordline is not yet activated (i.e. in an ‘off’ state), then a first voltage will be measured across the selected bus bar and the selected wordline. Once the OTS element bridging the selected bus bar and the selected wordline activates (i.e. turns ‘on’) then the voltage level between the selected bus bar and the selected wordline will drop to a second voltage. Due to inherent resistances in the bus bar and wordline, the voltage will not usually drop to zero volts, but instead will drop to a level below a threshold level that indicates the OTS element has activated. Responsive to detecting the activation of the OTS element, the activation voltage can be removed and current/signals/data can flow from the selected bus bar, through the bridging OTS element, through a short portion of the selected wordline, and into the one or more target embedded devices. A return current path from the embedded devices to control circuitry can be formed by further conductive elements, such as bus bars, bit/word lines, or other conductive elements. FIG. 1 shows examples of these return current pathways in elements 122.

The included descriptions and figures depict specific embodiments to teach those skilled in the art how to make and use the best mode. For the purpose of teaching inventive principles, some conventional aspects have been simplified or omitted. Those skilled in the art will appreciate variations from these embodiments that fall within the scope of the invention. Those skilled in the art will also appreciate that the features described above can be combined in various ways to form multiple embodiments. As a result, the invention is not limited to the specific embodiments described above, but only by the claims and their equivalents.

What is claimed is:

1. An integrated circuit power distribution system, comprising:
a first power distribution bus coupled to a current source and a threshold bridge element;
a second power distribution bus coupled to one or more target devices and the threshold bridge element; and
the threshold bridge element comprising a bridge material with properties that pass current responsive to application of a threshold voltage across the bridge material.

2. The system of claim 1, wherein the threshold bridge element comprises an ovonic threshold switch element.

3. The system of claim 1, comprising:
the threshold bridge element further comprising a first electrode coupled to the first power distribution bus and a second electrode coupled to the second power distribution bus;
the first electrode configured to pass the current from the first power distribution bus to the bridge material and inhibit migration of material of the first power distribution bus into the bridge material; and
the second electrode configured to pass the current from the bridge material to the second power distribution bus and inhibit migration of material comprising the second power distribution bus into the bridge material.

4. The system of claim 1, comprising:
the first power distribution bus spanning along a first axis in a first layer of the integrated circuit and the second power distribution bus spanning along a second axis in a second layer of the integrated circuit, the second axis perpendicular to the first axis.

5. The system of claim 4, comprising:
the second power distribution bus comprising a wordline of a memory array that receives power from the first power distribution bus through the threshold bridge element.

6. The system of claim 4, comprising:
the threshold bridge element disposed in a third layer of the integrated circuit between the first layer and the second layer.

7. The system of claim 1, comprising:
the integrated circuit comprising a non-volatile memory (NVM) array, with the one or more target devices each comprising NVM devices.

8. The system of claim 7, comprising:
each of the NVM devices having a corresponding threshold bridge element to select individual ones of the NVM devices.

9. The system of claim 1, wherein the threshold voltage is applied to the threshold bridge element by applying at least the threshold voltage between the first power distribution bus and the second power distribution bus.

10. The system of claim 9, further comprising:
a control circuit configured to apply the threshold voltage between the first power distribution bus and the second power distribution bus; and
the control circuit configured to detect when the threshold bridge element passes the current and responsively remove the threshold voltage, wherein the threshold bridge element continues to pass the current after removal of the threshold voltage.

11. A method of operating a power distribution system in an integrated circuit, the method comprising:
applying an activation voltage across a threshold bridge element disposed between a first power distribution bus and a second power distribution bus, the first power distribution bus coupled to a current source and the second power distribution bus coupled to one or more target devices; and
removing the activation voltage after the threshold bridge element passes current supplied by the current source, wherein the threshold bridge element continues to pass the current after removal of the activation voltage.

12. The method of claim 11, wherein the threshold bridge element comprises an ovonic threshold switch element.

13. The method of claim 11, wherein the threshold bridge element further comprises a first electrode coupled to the first power distribution bus and a second electrode coupled to the second power distribution bus, wherein the first electrode passes the current from the first power distribution bus to the bridge material and reduces migration of material of the first power distribution bus into the bridge material, and wherein the second electrode passes the current from the bridge material to the second power distribution bus and reduces migration of material comprising the second power distribution bus into the bridge material.

14. The method of claim 11, further comprising:
detecting when the threshold bridge element passes the current and responsively removing the threshold voltage.

15. The method of claim 11, wherein the integrated circuit comprises a non-volatile memory (NVM) array, with the one or more target devices each comprising NVM devices.

16. The method of claim 15, wherein each of the NVM devices have a corresponding threshold bridge element to select individual ones of the NVM devices.

17. A solid state data storage array, comprising:
one or more wordlines each coupling sets of non-volatile memory (NVM) devices configured to store bits of data;
each of the wordlines coupled by ovonic switching elements to power distribution links; and
the ovonic switching elements each configured to pass current from a connected power distribution link through an associated wordline to at least one NVM device responsive to application of a threshold voltage across the connected power distribution link and the associated wordline.

18. The solid state data storage array of claim 17, comprising:
a control circuit configured to detect when selected ones of the ovonic switching elements activate and responsively cease application of the threshold voltage, wherein the selected ones of the ovonic switching elements continue to remain activated after removal of the threshold voltage.

19. The solid state data storage array of claim 17, wherein each of the wordlines run perpendicular to the plurality of power distribution links;
the power distribution links spanning along a first axis in a first layer of an integrated circuit forming the solid state data storage array;
the wordlines spanning along a second axis in a second layer of the integrated circuit, the second axis perpendicular to the first axis; and
the ovonic switching elements disposed in a third layer of the integrated circuit between the first layer and the second layer.

20. The solid state data storage array of claim 17, wherein the NVM devices comprise resistive random access memory (ReRAM) devices.
